(19) United States
(12) Patent Application Publication
(10) Pub. No.: US 2016/0072052 A1
(43) Pub. Date: Mar. 10, 2016

(54) MAGNETORESISTIVE ELEMENT AND METHOD OF MANUFACTURING THE SAME

(71) Applicant: KABUSHIKI KAISHA TOSHIBA, Tokyo (JP)

(72) Inventor: Kenji NOMA, Yokohama Kanagawa (JP)

(73) Assignee: KABUSHIKI KAISHA TOSHIBA, Tokyo (JP)

(21) Appl. No.: 14/562,087

(22) Filed: Dec. 5, 2014

Related U.S. Application Data
(60) Provisional application No. 62/048,092, filed on Sep. 9, 2014.

(51) Int. Cl. H01L 43/10; H01L 43/12

(52) U.S. Cl. CPC H01L 43/10; H01L 43/12; H01L 43/02

(57) ABSTRACT

According to one embodiment, a magnetoresistive element includes a first magnetic layer having an invariable magnetization, a second magnetic layer having a variable magnetization, and an insulating layer between the first and second magnetic layers. The insulating layer includes at least one of a nickel oxide, an iron oxide, a cobalt oxide, a manganese oxide, LaMnO₃ and ZnFe₂O₄.

### CROSS-REFERENCE TO RELATED APPLICATIONS

This application claims the benefit of U.S. Provisional Application No. 62/048,092, filed Sep. 9, 2014, the entire contents of which are incorporated herein by reference.

### FIELD

Embodiments described herein relate generally to a magnetoresistive element and a method of manufacturing the same.

### BACKGROUND

A magnetoresistive element has a basic structure comprising a reference layer having an invariable magnetization, a storage layer having a variable magnetization, and a nonmagnetic layer (tunnel barrier layer) between the reference layer and the storage layer. When the magnetization direction of the reference layer is the same as that of the storage layer, the magnetoresistive element is in a low-resistance state (parallel state). This state is called, for example, a 0-write state. When the magnetization direction of the reference layer is opposite to that of the storage layer, the magnetoresistive element is in a high-resistance state (anti-parallel state). This state is called, for example, a 1-write state.

For example, when spin-transfer-torque (STT) writing is employed, a write operation which puts the magnetoresistive element into a parallel or anti-parallel state is performed by supplying a spin injection current to the magnetoresistive element. In terms of disturb, retention and the like, the magnetization inversion property (hysteresis curve) of the storage layer of the magnetoresistive element is preferably symmetrical in a 0/1-writing. However, the storage layer receives a stray magnetic field from the reference layer at all times. Because of this, the magnetization inversion property of the storage layer tends to shift to a direction which makes it difficult to perform a 1-writing which changes the magnetization direction of the storage layer to a direction opposite to the magnetization direction of the reference layer.

In order to cancel the shift of the magnetization inversion property of the storage layer, a technique which adds, to the magnetoresistive element, a shift cancelling layer having a magnetization direction opposite to the magnetization direction of the reference layer is considered. However, the shift cancelling layer needs to be very thick to symmetrize the magnetization inversion property of the storage layer by using the shift cancelling layer. This results in disadvantage in the miniaturization process of the magnetoresistive element.

### BRIEF DESCRIPTION OF THE DRAWINGS

FIG. 1A, FIG. 1B, FIG. 10 and FIG. 1D are cross-sectional views showing a magnetoresistive element according to a first embodiment.

FIG. 2A and FIG. 2B are cross-sectional views showing a magnetoresistive element according to a second embodiment.

FIG. 3A and FIG. 3B are cross-sectional views showing a magnetoresistive element according to a third embodiment.

FIG. 4 shows a shift cancelling effect.

FIG. 5 shows an example of a 1-writing operation.

FIG. 6 shows an example of a 0-writing operation.

FIG. 7A and FIG. 7B show a first example of a method of manufacturing a magnetoresistive element.

FIG. 8A and FIG. 8B show a second example of the method of manufacturing the magnetoresistive element.

FIG. 9 is a cross-sectional view showing a memory cell as an application example.

FIG. 10 and FIG. 11 are cross-sectional views showing modification examples of area X of FIG. 9.

FIG. 12 is a cross-sectional view showing a first example of a magnetoresistive element of FIG. 9.

FIG. 13 is a cross-sectional view showing a second example of the magnetoresistive element of FIG. 9.

FIG. 14 is a plan view showing an example of a memory cell array.

FIG. 15 is a cross-sectional view taken along line XV-XV of FIG. 14.

FIG. 16 is a cross-sectional view taken along line XVI-XVI of FIG. 14.

FIG. 17 is a cross-sectional view taken along line XVII-XVII of FIG. 14.

FIG. 18 is a circuit diagram showing an equivalent circuit of the memory cell array of FIG. 14 to FIG. 17.

FIG. 19 is a block diagram showing an example of a memory system in a processor.

### DETAILED DESCRIPTION

In general, according to one embodiment, a magnetoresistive element comprises: a first magnetic layer having an invariable magnetization; a second magnetic layer having a variable magnetization; and an insulating layer between the first and second magnetic layers. The insulating layer includes at least one of a nickel oxide, an iron oxide, a cobalt oxide, a manganese oxide, LaMnO₃ and ZnFe₂O₄.

### 1. Magnetoresistive Element

### (1) Structure

### First Embodiment

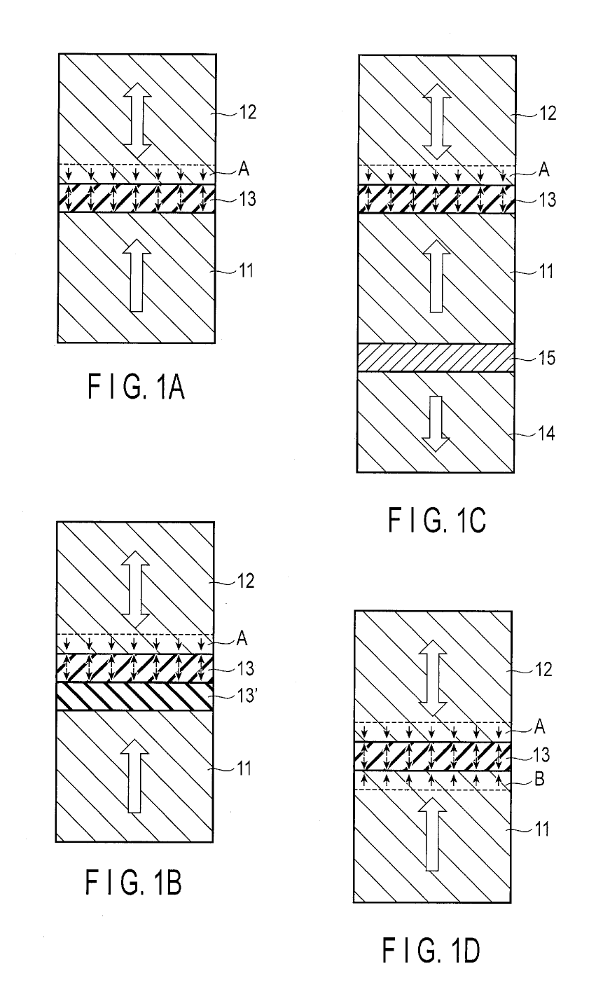

FIG. 1A, FIG. 1B and FIG. 10 show a first embodiment of a magnetoresistive element.

The first embodiment has a feature in respect that a nonmagnetic insulating layer (tunnel barrier layer) between a first magnetic layer (reference layer) 11 having an invariable magnetization and a second magnetic layer (storage layer) 12 having a variable magnetization comprises an antiferromagnetic insulating layer 13.

Invariable magnetization means that the magnetization direction before and after writing is the same. Variable magnetization means that the magnetization direction before writing may change to the opposite direction after writing.

Writing refers to spin transfer writing which applies spin torque to the magnetization of the second magnetization layer 12 by supplying a write current (spin-polarized electrons) to the magnetoresistive element.

In the first embodiment, the top-and-bottom relationship between the first magnetic layer 11 and the second magnetic layer 12 is not particularly limited. The second magnetic layer 12 may be provided above the magnetic layer 11. The first magnetic layer 11 may be provided above the second magnetic layer 12.

The first embodiment employs, as an example, a perpendicular-magnetization magnetoresistive element, which is advantageous to miniaturization, reduction in write current, magnetization stability (retention) and the like. However, instead of it, an in-plane-magnetization magnetoresistive element may be adopted.

FIG. 1A, FIG. 1B and FIG. 1C schematically show the magnetoresistive element. The size of each element of the magnetoresistive element in the figures is different from the actual size.

The magnetoresistive element of FIG. 1A comprises the first magnetic layer 11 having an invariable magnetization, the second magnetic layer 12 having a variable magnetization, and the antiferromagnetic insulating layer 13 between the first magnetic layer 11 and the second magnetic layer 12.

The magnetization direction of remanent magnetization of the first magnetic layer 11 is a direction in which the first and second magnetic layers 11 and 12 are stacked (perpendicular direction). In the first embodiment, the remanent magnetization of the first magnetic layer 11 points to the antiferromagnetic insulating layer 13 side. However, the remanent magnetization of the first magnetic layer 11 may point to a side opposite to the antiferromagnetic insulating layer 13 side.

The antiferromagnetic insulating layer 13 functions as a tunnel barrier layer. Therefore, the thickness of the antiferromagnetic insulating layer 13 in the perpendicular direction is preferably several nanometers or less; for example, approximately 1 nm.

The second magnetic layer 12 includes area A which is magnetically coupled with the antiferromagnetic insulating layer 13 by an exchange coupling and which has a magnetization direction opposite to the magnetization direction of the first magnetic layer 11.

Area A produces a second stray magnetic field which is opposite to a first stray magnetic field produced by the first magnetic layer 11. Since the first and second stray magnetic fields are offset each other, it is possible to cancel the shift of the magnetization inversion property of the second magnetic layer 12.

Area A fixes the magnetization direction of the second magnetic layer 12 to the perpendicular direction. Area A also has an effect which improves the magnetization stability (retention) of the second magnetic layer 12 after writing by the exchange coupling between the second magnetic layer 12 and the antiferromagnetic insulating layer 13.

However, since the antiferromagnetic insulating layer 13 functions as a tunnel barrier layer as stated above, its thickness in the perpendicular direction is very thin. Because of this, area A produced by the exchange coupling between the second magnetic layer 12 and the antiferromagnetic insulating layer 13 is a part of the second magnetic layer 12, and the other part functions as a storage layer having a variable magnetization.

The magnetoresistive element of FIG. 1B is a modification example of the magnetoresistive element of FIG. 1A.

Compared to the magnetoresistive element of FIG. 1A, the magnetoresistive element of FIG. 1B has a feature in respect that a nonmagnetic insulating layer 13′ is further provided between the first magnetic layer 11 having an invariable magnetization and the antiferromagnetic insulating layer 13. In the other respects, the magnetoresistive element of FIG. 1B is the same as the magnetoresistive element of FIG. 1A. Therefore, explanations of the same structures are omitted.

The nonmagnetic insulating layer 13′ is an insulating layer of MgO, etc.

In this modification example, the tunnel barrier layer comprises the antiferromagnetic insulating layer 13 and the nonmagnetic insulating layer 13′.

Therefore, the total thickness of the antiferromagnetic insulating layer 13 and the nonmagnetic insulating layer 13′ in the perpendicular direction is preferably several nanometers or less; for example, approximately 1 nm.

The magnetoresistive element of FIG. 1C is another modification example of the magnetoresistive element of FIG. 1A.

Compared to the magnetoresistive element of FIG. 1A, the magnetoresistive element of FIG. 1C has a feature in respect that it further comprises a third magnetic layer 14 having an invariable magnetization and having a magnetization direction opposite to the magnetization direction of the first magnetic layer 11. In the other respects, the magnetoresistive element of FIG. 1C is the same as the magnetoresistive element of FIG. 1A. Therefore, explanations of the same structures are omitted.

As the third magnetic layer 14 has a magnetization direction opposite to the magnetization direction of the first magnetic layer 11, the third magnetic layer 14 functions as a shift cancelling layer which cancels the shift of the magnetization inversion property of the second magnetic layer 12. In this modification example, a nonmagnetic-and-conductive layer 15 is provided between the first magnetic layer 11 and the third magnetic layer 14. However, the nonmagnetic-and-conductive layer 15 may be omitted.

In this manner, the shift of the magnetization inversion property of the second magnetic layer 12 may be cancelled by both area A in the second magnetic layer 12 and the third magnetic layer 14. In this case, the thickness of the third magnetic layer 14 in the perpendicular direction can be reduced compared to the example in which area A is not provided. Since the size of the magnetoresistive element in the perpendicular direction can be reduced, this case is advantageous to miniaturization.

The magnetoresistive element of FIG. 1D is another modification example of the magnetoresistive element of FIG. 1A.

The magnetoresistive element of FIG. 1D is different from the magnetoresistive element of FIG. 1A at the following point.

The first magnetic layer 11 includes area B which is magnetically coupled with the antiferromagnetic insulating layer 13 by an exchange coupling. Area B fixes the magnetization direction of the first magnetic layer 11 to the perpendicular direction. Area B also has an effect which improves the magnetization stability of the first magnetic layer 11.

Area B of FIG. 1D may apply the structure of FIG. 1C.

In the magnetoresistive element of each of FIG. 1A, FIG. 1B, FIG. 10 and FIG. 1D, the tunnel barrier layer includes the antiferromagnetic insulating layer 13. On the other hand, to improve the MR ratio of the magnetoresistive element (magnetoresistive ratio), the tunnel barrier layer preferably has a material comprising an NaCl structure which is (001)-oriented in the perpendicular direction, such as MgO.

The antiferromagnetic insulating layer 13 also preferably has a material comprising an NaCl structure which is (001)-oriented in the perpendicular direction.

This kind of material is, for example, a nickel oxide, an iron oxide, a cobalt oxide or a manganese oxide. These materials can be used as the antiferromagnetic insulating layer 13 comprising an NaCl structure which is (001)-oriented in the perpendicular direction.

The antiferromagnetic insulating layer 13 may have a material other than the material comprising an NaCl structure which is (001)-oriented in the perpendicular direction. For example, LaMnO₃ comprising a perovskite structure or ZnFe₂O₄ comprising a spinel structure can be used as the antiferromagnetic insulating layer 13.

The antiferromagnetic insulating layer 13 may include a plurality kind of antiferromagnetic materials. For example, at least two materials selected from a group of NiO, FeO, CoO and MnO may mix or stack, and at least two materials selected from a group of NiFeO, CoFeO, FeO, MnFeO and ZnFeO may mix or stack. The antiferromagnetic insulating layer 13 may form by combining LaMnO and LaCoMnO or by combining LaMnO and LaNiMnO. NiO is effective as the antiferromagnetic insulating layer 13 because NiO has a high neel temperature and has an NaCl structure same as MgO.

### Second Embodiment

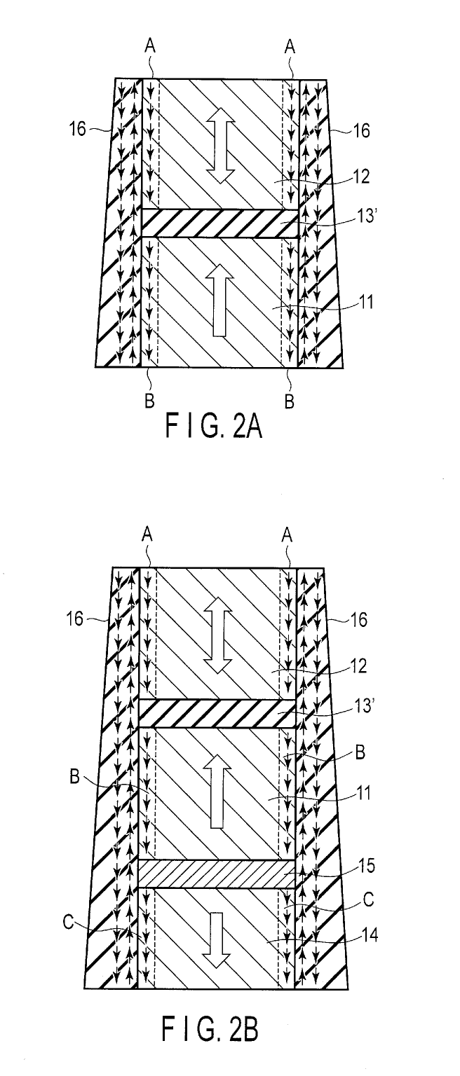

FIG. 2A and FIG. 2B show a second embodiment of a magnetoresistive element.

The second embodiment has a feature in respect that, in a direction (in-plane direction) perpendicular to a direction (perpendicular direction) in which a first magnetic layer (reference layer) 11 having an invariable magnetization and a second magnetic layer (storage layer) 12 having a variable magnetization are stacked, an antiferromagnetic insulating layer 16 is adjacent to a sidewall of the second magnetic layer 12.

In the second embodiment, similarly, the top-and-bottom relationship between the first magnetic layer 11 and the second magnetic layer 12 is not particularly limited. The second magnetic layer 12 may be provided above the first magnetic layer 11. The first magnetic layer 11 may be provided above the second magnetic layer 12.

In a manner similar to the first embodiment, a perpendicular-magnetization magnetoresistive element is employed as an example in the second embodiment. However, instead of it, an in-plane-magnetization magnetoresistive element may be adopted.

FIG. 2A and FIG. 2B schematically show the magnetoresistive element. The size of each element of the magnetoresistive element in the figures is different from the actual size.

The magnetoresistive element of FIG. 2A comprises the first magnetic layer 11 having an invariable magnetization, the second magnetic layer 12 having a variable magnetization and a nonmagnetic insulating layer 13′ between the first magnetic layer 11 and the second magnetic layer 12.

The magnetization direction of remanent magnetization of the first magnetic layer 11 is perpendicular. In the second embodiment, the remanent magnetization of the first magnetic layer 11 points to the nonmagnetic insulating layer 13′ side. However, the remanent magnetization of the first magnetic layer 11 may point to a side opposite to the nonmagnetic insulating layer 13′ side.

The nonmagnetic insulating layer 13′ is, for example, MgO. The nonmagnetic insulating layer 13′ functions as a tunnel barrier layer. Therefore, the thickness of the nonmagnetic insulating layer 13′ in the perpendicular direction is preferably several nanometers or less; for example, approximately 1 nm.

The antiferromagnetic insulating layer 16 is adjacent to the sidewalls of the first and second magnetic layers 11 and 12 in the in-plane direction.

The second magnetic layer 12 includes area A which is magnetically coupled with the antiferromagnetic insulating layer 16 by an exchange coupling and which has a magnetization direction opposite to the magnetization direction of the first magnetic layer 11. The first magnetic layer 11 includes area B which is magnetically coupled with the antiferromagnetic insulating layer 16 by an exchange coupling and which has a magnetization direction opposite to the magnetization direction of the first magnetic layer 11.

Areas A and B produce a second stray magnetic field opposite to a first stray magnetic field produced by the first magnetic layer 11. Since the first and second stray magnetic fields are offset each other, it is possible to cancel the shift of the magnetization inversion property of the second magnetic layer 12.

Area A fixes the magnetization direction of the second magnetic layer 12 to the perpendicular direction. Area A also has an effect which improves the magnetization stability (retention) of the second magnetic layer 12 after writing by the exchange coupling between the second magnetic layer 12 and the antiferromagnetic insulating layer 16.

However, as a sidewall insulating layer, the antiferromagnetic insulating layer 16 is adjacent to only the sidewall of the second magnetic layer 12. Therefore, the length in which the second magnetic layer 12 is adjacent to the antiferromagnetic insulating layer 16 in the perpendicular direction is generally shorter than the length of the second magnetic layer 12 in the in-plane direction. Thus, area A produced by the exchange coupling between the second magnetic layer 12 and the antiferromagnetic insulating layer 16 is a part of the second magnetic layer 12. The other part functions as a storage layer having a variable magnetization.

The magnetoresistive element of FIG. 2B is a modification example of the magnetoresistive element of FIG. 2A.

Compared to the magnetoresistive element of FIG. 2A, the magnetoresistive element of FIG. 2B has a feature in respect that it further comprises a third magnetic layer 14 having an invariable magnetization and having a magnetization direction opposite to the magnetization direction of the first magnetic layer 11. In the other respects, the magnetoresistive element of FIG. 2B is the same as the magnetoresistive element of FIG. 2A. Therefore, explanations of the same structures are omitted.

As the third magnetic layer 14 has the magnetization direction opposite to the magnetization direction of the first magnetic layer 11, the third magnetic layer 14 functions as a shift cancelling layer which cancels the shift of magnetization inversion property of the second magnetic layer 12. In this modification example, a nonmagnetic-and-conductive layer 15 is provided between the first magnetic layer 11 and the third magnetic layer 14. However, the nonmagnetic-and-conductive layer 15 may be omitted.

The antiferromagnetic insulating layer 16 is adjacent to a sidewall of the third magnetic layer 14 in the in-plane direction. Thus, the third magnetic layer 14 includes area C which is magnetically coupled with the antiferromagnetic insulating layer 16 by an exchange coupling and which has a magnetization direction opposite to the magnetization direction of the first magnetic layer 11.

In this manner, the shift of magnetization inversion property of the second magnetic layer 12 may be cancelled by both area A in the second magnetic layer 12 and the third magnetic layer 14. In this case, the thickness of the third magnetic layer 14 in the perpendicular direction can be reduced compared to the example in which area A is not provided. Since the size of the magnetoresistive element in the perpendicular direction can be reduced, this modification example is advantageous to miniaturization.

As the first magnetic layer 11 is close to the second magnetic layer 12, the first stray magnetic field produced by the first magnetic layer 11 is applied to the whole second magnetic layer 12. On the other hand, the third magnetic layer 14 is far from the second magnetic layer 12. Because of this, the cancelling magnetic field produced by the third magnetic layer 14 is mainly applied to the central portion of the second magnetic layer 12.

The cancelling magnetic field produced by the third magnetic layer 14 cannot sufficiently offset the first stray magnetic field applied to an end portion of the second magnetic layer 12 in the in-plane direction.

In FIG. 2B, the first stray magnetic field applied to an end portion of the second magnetic layer 12 in the in-plane direction can be offset by the second stray magnetic field produced by area A.

In the magnetoresistive element of each of FIG. 2A and FIG. 2B, the antiferromagnetic insulating layer 16 functions as a sidewall insulating layer of the magnetoresistive element. The antiferromagnetic layer 16 does not influence the MR ratio of the magnetoresistive element. This is different from the first embodiment. Thus, restrictions in, for example, the crystal orientation and the crystal structure are not applied to the antiferromagnetic insulating layer 16. The antiferromagnetic insulating layer 16 can be arbitrarily selected from all of the antiferromagnetic insulating layers.

In a manner similar to the first embodiment, a material comprising an NaCl structure which is (001)-oriented in the perpendicular direction, such as a nickel oxide, an iron oxide, a cobalt oxide and a manganese oxide can be used for the antiferromagnetic insulating layer 16. LaMnO₃ comprising a perovskite structure or ZnFe₂O₄ comprising a spinel structure can be also used for the antiferromagnetic insulating layer 16.

### Third Embodiment

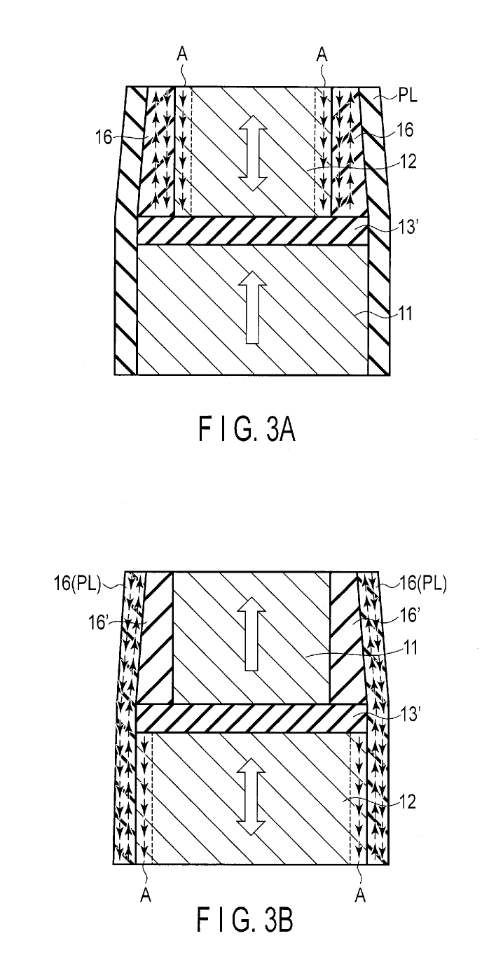

FIG. 3A and FIG. 3B show a third embodiment of a magnetoresistive element.

In a manner similar to the second embodiment, the third embodiment has a feature in respect that, in a direction (in-plane direction) perpendicular to a direction (perpendicular direction) in which a first magnetic layer (reference layer) 11 having an invariable magnetization and a second magnetic layer (storage layer) 12 having a variable magnetization direction are stacked, an antiferromagnetic insulating layer 16 is adjacent to a sidewall of the second magnetic layer 12.

In the third embodiment, the antiferromagnetic insulating layer 16 is adjacent to the sidewall of the second magnetic layer 12 in the in-plane direction while the antiferromagnetic insulating layer 16 is not adjacent to a sidewall of the first magnetic layer 11 in the in-plane direction.

In a manner similar to the first embodiment, a perpendicular-magnetization magnetoresistive element is used as an example in the third embodiment. However, instead of it, an in-plane-magnetization magnetoresistive element may be adopted.

FIG. 3A and FIG. 3B schematically show the magnetoresistive element. The size of each element of the magnetoresistive element in the figures is different from the actual size.

The magnetoresistive element of FIG. 3A comprises the first magnetic layer 11 having an invariable magnetization, the second magnetic layer 12 having a variable magnetization, and a nonmagnetic insulating layer 13′ between the first magnetic layer 11 and the second magnetic layer 12. In this magnetoresistive element, the first magnetic layer 11 is provided under the second magnetic layer 12. This type is called a bottom-pin type. In this case, the size of the second magnetic layer 12 in the in-plane direction is smaller than the size of the first magnetic layer 11 in the in-plane direction.

The magnetization direction of remanent magnetization of the first magnetic layer 11 is perpendicular. In FIG. 3A, the remanent magnetization of the first magnetic layer 11 points to the nonmagnetic insulating layer 13′ side. However, the remanent magnetization of the first magnetic layer 11 may point to a side opposite to the nonmagnetic insulating layer 13′ side.

The nonmagnetic insulating layer 13′ is, for example, MgO. The nonmagnetic insulating layer 13′ functions as a tunnel barrier layer. Thus, the thickness of the nonmagnetic insulating layer 13′ in the perpendicular direction is preferably several nanometers or less; for example, approximately 1 nm.

The antiferromagnetic insulating layer 16 is adjacent to the sidewall of the second magnetic layer 12 in the in-plane direction. The second magnetic layer 12 includes area A which is magnetically coupled with the antiferromagnetic insulating layer 16 by an exchange coupling and which has a magnetization direction opposite to the magnetization direction of the first magnetic layer 11.

Area A produces a second stray magnetic field opposite to a first stray magnetic field produced by the first magnetic layer 11. Since the first and second stray magnetic fields are offset each other, it is possible to cancel the shift of magnetization inversion property of the second magnetic layer 12.

Area A fixes the magnetization direction of the second magnetic layer 12 to the perpendicular direction. Area A also has an effect which improves the magnetization stability (retention) of the second magnetic layer 12 after writing by the exchange coupling between the second magnetic layer 12 and the antiferromagnetic insulating layer 16.

However, as a sidewall insulating layer, the antiferromagnetic insulating layer 16 is adjacent to only the sidewall of the second magnetic layer 12. Therefore, the length in which the second magnetic layer 12 is adjacent to the antiferromagnetic insulating layer 16 in the perpendicular direction is generally shorter than the length of the second magnetic layer 12 in the in-plane direction. Thus, area A produced by the exchange coupling between the second magnetic layer 12 and the antiferromagnetic insulating layer 16 is a part of the second magnetic layer 12. The other part functions as a storage layer having a variable magnetization.

A protective insulating layer PL is, for example, a silicon nitride, and covers the magnetoresistive element.

The magnetoresistive element of FIG. 3B comprises the first magnetic layer 11 having an invariable magnetization, the second magnetic layer 12 having a variable magnetization, and the nonmagnetic insulating layer 13′ between the first magnetic layer 11 and the second magnetic layer 12. In this magnetoresistive element, the first magnetic layer 11 is provided above the second magnetic layer 12. This type is called a top-pin type. In this case, the size of the second magnetic layer 12 in the in-plane direction is larger than the size of the first magnetic layer 11 in the in-plane direction.

The magnetization direction of remanent magnetization of the first magnetic layer 11 is perpendicular. In FIG. 3B, the remanent magnetization of the first magnetic layer 11 points to a side opposite to the nonmagnetic insulating layer 13′ side. However, the remanent magnetization of the first magnetic layer 11 may point to the nonmagnetic insulating layer 13′ side.

The nonmagnetic insulating layer 13′ is, for example, MgO. The nonmagnetic insulating layer 13′ functions as a tunnel barrier layer. Therefore, the thickness of the nonmagnetic insulating layer 13′ in the perpendicular direction is preferably several nanometers or less; for example, approximately 1 nm.

A sidewall insulating layer (nonmagnetic insulating layer) 16′ is adjacent to the sidewall of the first magnetic layer 11 in the in-plane direction.

The antiferromagnetic insulating layer 16 is adjacent to the sidewall of the second magnetic layer 12 in the in-plane direction. The second magnetic layer 12 includes area A which is magnetically coupled with the antiferromagnetic insulating layer 16 by an exchange coupling and which has a magnetization direction opposite to the magnetization direction of the first magnetic layer 11.

Area A produces the second stray magnetic field opposite to the first stray magnetic field produced by the first magnetic layer 11. Since the first and second stray magnetic fields are offset each other, it is possible to cancel the shift of magnetization inversion property of the second magnetic layer 12.

Area A fixes the magnetization direction of the second magnetic layer 12 to the perpendicular direction. Area A also has an effect which improves the magnetization stability (retention) of the second magnetic layer 12 after writing by the exchange coupling between the second magnetic layer 12 and the antiferromagnetic insulating layer 16.

However, as a sidewall insulating layer, the antiferromagnetic insulating layer 16 is adjacent to only the sidewall of the second magnetic layer 12. Therefore, the length in which the second magnetic layer 12 is adjacent to the antiferromagnetic insulating layer 16 in the perpendicular direction is generally shorter than the length of the second magnetic layer 12 in the in-plane direction. Thus, area A produced by the exchange coupling between the second magnetic layer 12 and the antiferromagnetic insulating layer 16 is a part of the second magnetic layer 12. The other part functions as a storage layer having a variable magnetization.

The antiferromagnetic insulating layer 16 may function as the protective insulating layer PL which protects the magnetoresistive element.

In the magnetoresistive element of each of FIG. 3A and FIG. 3B, the antiferromagnetic insulating layer 16 functions as a sidewall insulating layer of the magnetoresistive element. The antiferromagnetic insulating layer 16 does not influence the MR ratio of the magnetoresistive element. This is different from the first embodiment. Thus, restrictions in, for example, the crystal orientation and the crystal structure are not applied to the antiferromagnetic insulating layer 16. The antiferromagnetic insulating layer 16 can be arbitrarily selected from all of the antiferromagnetic insulating layers.

In a manner similar to the first embodiment, a material comprising an NaCl structure which is (001)-oriented in the perpendicular direction, such as a nickel oxide, an iron oxide, a cobalt oxide and a manganese oxide can be used for the antiferromagnetic insulating layer 16. LaMnO₃ comprising a perovskite structure or ZnFe₂O₄ comprising a spinel structure can be also used for the antiferromagnetic insulating layer 16.

### (2) Shift Cancelling Effect

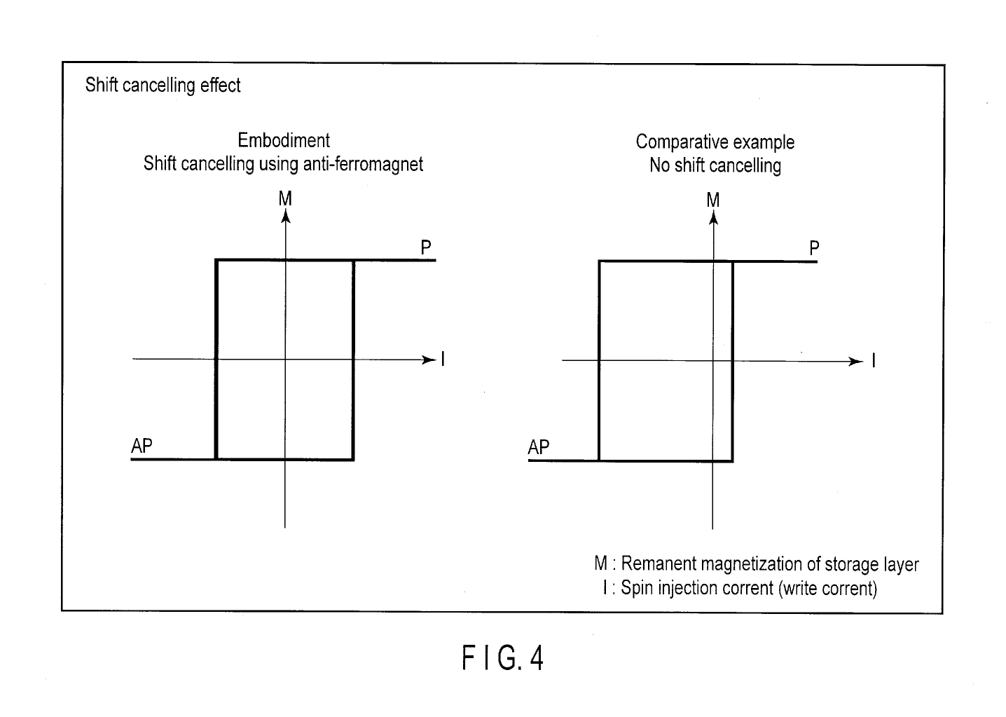

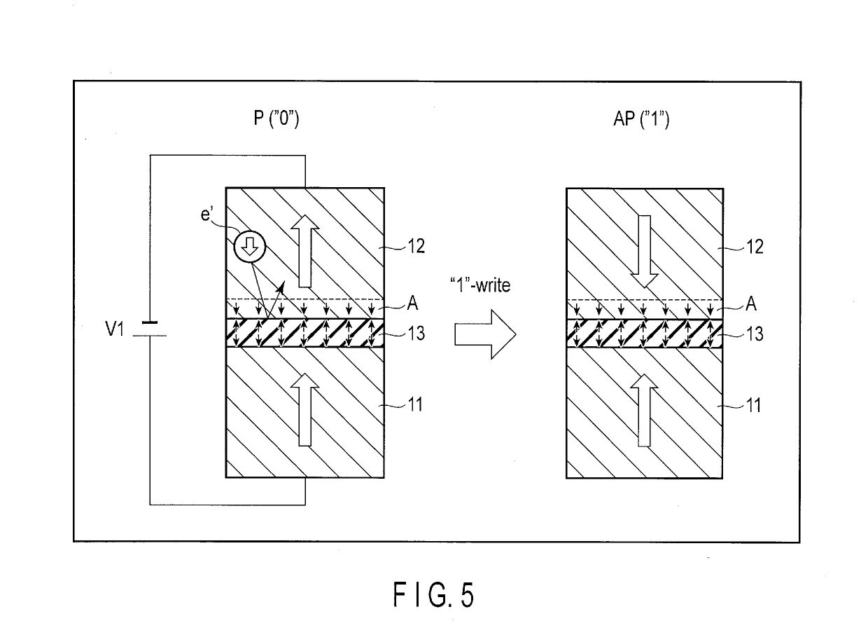

FIG. 4 shows a shift cancelling effect according to the first to third embodiments.

In the comparative example shown in FIG. 4, the structure of one of the embodiments is employed, but the shift cancelling using an antiferromagnetic insulating layer is not performed. For example, when the example of FIG. 1A is applied, the embodiment has the structure identical to the structure of FIG. 1A. In the comparative example, the antiferromagnetic insulating layer 13 of FIG. 1A is changed to a nonmagnetic insulating layer.

In the graph showing the hysteresis curve of FIG. 4, the magnitude of the write current is indicated in the horizontal axis, and the strength of the remanent magnetization of the second magnetic layer (storage layer) is indicated in the vertical axis.

As is clear from FIG. 4, it is possible to cancel the shift of magnetization inversion property of the second magnetic layer (storage layer) by adding an antiferromagnetic insulating layer to the magnetoresistive element.

### (3) Writing Operation

In the magnetoresistive element of each of the first to third embodiments, a writing operation is performed by supplying a write current (spin-polarized electrons) to the magnetoresistive element. Hereinafter, the writing operation is explained by using the structure of FIG. 1A as an example.

A state in which the magnetization directions of the first and second magnetic layers 11 and 12 are the same is referred to as a parallel state (0-state) P. A state in which the magnetization directions of the first and second magnetic layers 11 and 12 are opposite is referred to as an anti-parallel state (1-state) AP. The resistance of the magnetoresistive element in the parallel state P is lower than the resistance of the magnetoresistive element in the anti-parallel state AP.

This specification explains a writing operation which changes the magnetoresistive element from the parallel state P to the anti-parallel state AP with reference to FIG. 5.

For example, when the potential on the second magnetic layer 12 side is zero, and the potential on the first magnetic layer 11 side is positive potential V1, a write current flows from the first magnetic layer 11 to the second magnetic layer 12. At this time, electrons e⁻ flow from the second magnetic layer 12 to the first magnetic layer 11.

Of the electrons flowing from the second magnetic layer 12 to the first magnetic layer 11, electrons of the majority spin in the second magnetic layer 12, or in other words, electrons (upward) spin-polarized in the same direction as the magnetization (upward) of the first magnetic layer 11 are accumulated within the first magnetic layer 11. Of the electrons flowing from the second magnetic layer 12 to the first magnetic layer 11, electrons of the minority spin in the second magnetic layer 12, or in other words, electrons (downward) spin-polarized in a direction opposite to the magnetization (upward) of the first magnetic layer 11 are returned to the second magnetic layer 12 and apply spin torque to the magnetization within the second magnetic layer 12. Thus, the magnetization direction of the second magnetic layer 12 is changed to a direction (anti-parallel state) opposite to the magnetization direction of the first magnetic layer 11.

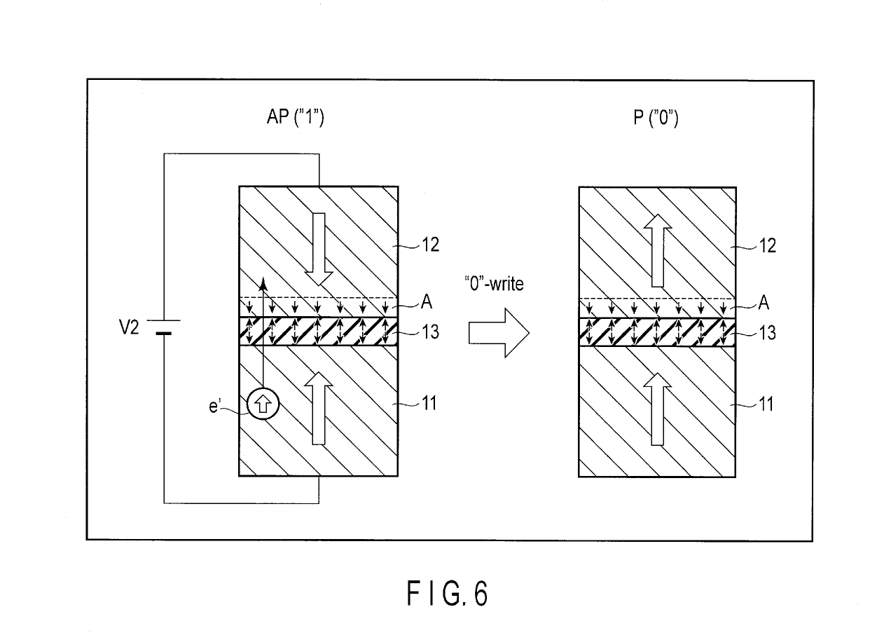

This specification explains a writing operation which changes the magnetoresistive element from the anti-parallel state AP to the parallel state P with reference to FIG. 6.

For example, when the potential on the second magnetic layer 12 side is positive potential V2, and the potential on the first magnetic layer 11 side is zero, a write current flows from the second magnetic layer 12 to the first magnetic layer 11. At this time, electrons e⁻ flow from the first magnetic layer 11 to the second magnetic layer 12.

Of the electrons flowing from the first magnetic layer 11 to the second magnetic layer 12, electrons of the minority spin in the second magnetic layer 12, or in other words, electrons (upward) spin-polarized in the same direction as the magnetization (upward) of the first magnetic layer 11 are accumulated within the second magnetic layer 12 and apply spin torque to the magnetization within the second magnetic layer 12. Thus, the magnetization direction of the second magnetic layer 12 is changed to the same direction (parallel state) as the magnetization direction of the first magnetic layer 11.

### (4) Manufacturing Method

This specification explains an example of a method of manufacturing the magnetoresistive element of each of the first to third embodiments.

This manufacturing method is mainly characterized by a method for an exchange coupling between the second magnetic layer and the antiferromagnetic insulating layer. Hereinafter, this specification explains the manufacturing method, using the structure of FIG. 1A and the structure of FIG. 2A as examples.

### First Example

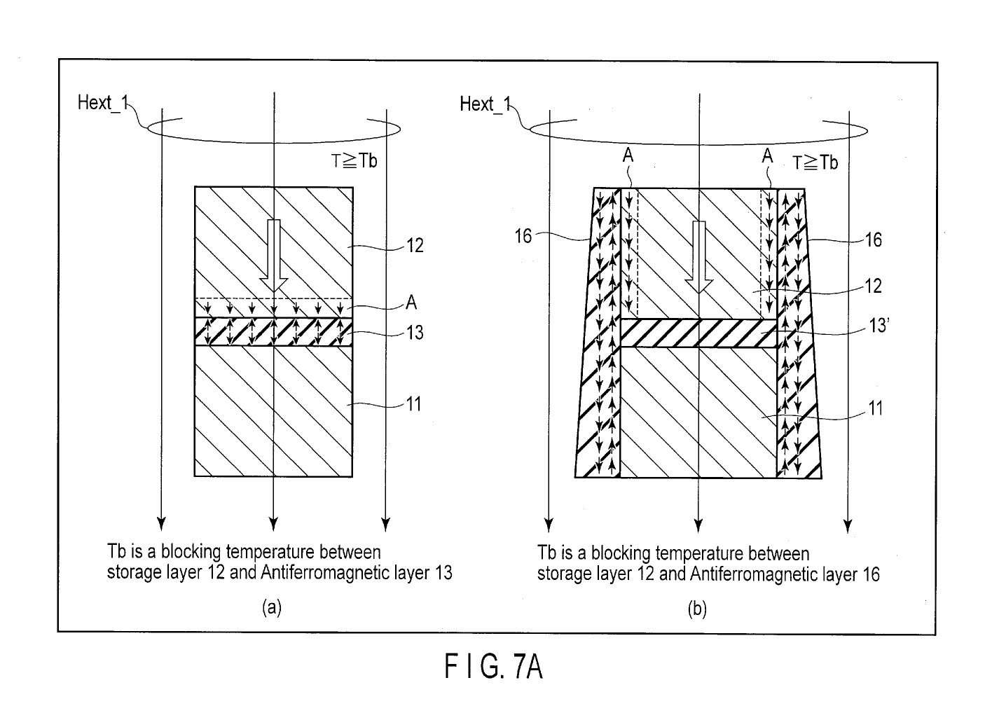

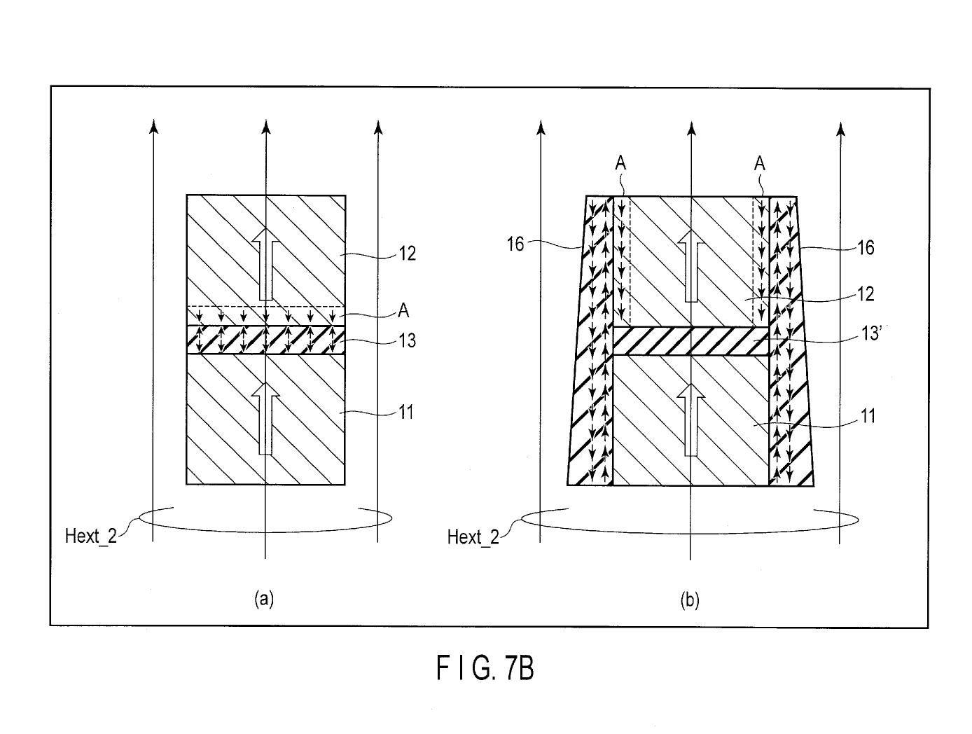

FIG. 7A and FIG. 7B show a first example of the manufacturing method. FIG. 7A(a) and FIG. 7B(a) correspond to FIG. 1A, and FIG. 7A(b) and FIG. 7B(b) correspond to FIG. 2A.

As shown in FIG. 7A, the magnetoresistive element comprising the first magnetic layer 11, the second magnetic layer 12 and the antiferromagnetic insulating layer 13, or the magnetoresistive element comprising the first magnetic layer 11, the second magnetic layer 12, the nonmagnetic insulating layer 13′ and the antiferromagnetic insulating layer 16 is formed.

Subsequently, in a state where external magnetic field Hext_1 having a first direction (downward) is applied, the temperature of the magnetoresistive element is, or specifically, the temperature of the wafer in which the magnetoresistive element is formed is increased to a temperature higher than a blocking temperature Tb between the second magnetic layer 12 and the antiferromagnetic insulating layers 13 and 16. After the increase, by changing the temperature to a temperature lower than the blocking temperature Tb, the second magnetic layer 12 is magnetically coupled with the antiferromagnetic insulating layers 13 and 16 by an exchange coupling, and area A whose magnetization direction is the first direction is formed in the second magnetic layer 12.

Next, as shown in FIG. 7B, after area A is formed in the second magnetic layer 12, external magnetic field Hext_2 having a second direction (upward) opposite to the first direction (downward) is applied to shift the magnetization direction of the second magnetic layer 12 to the second direction.

### Second Example

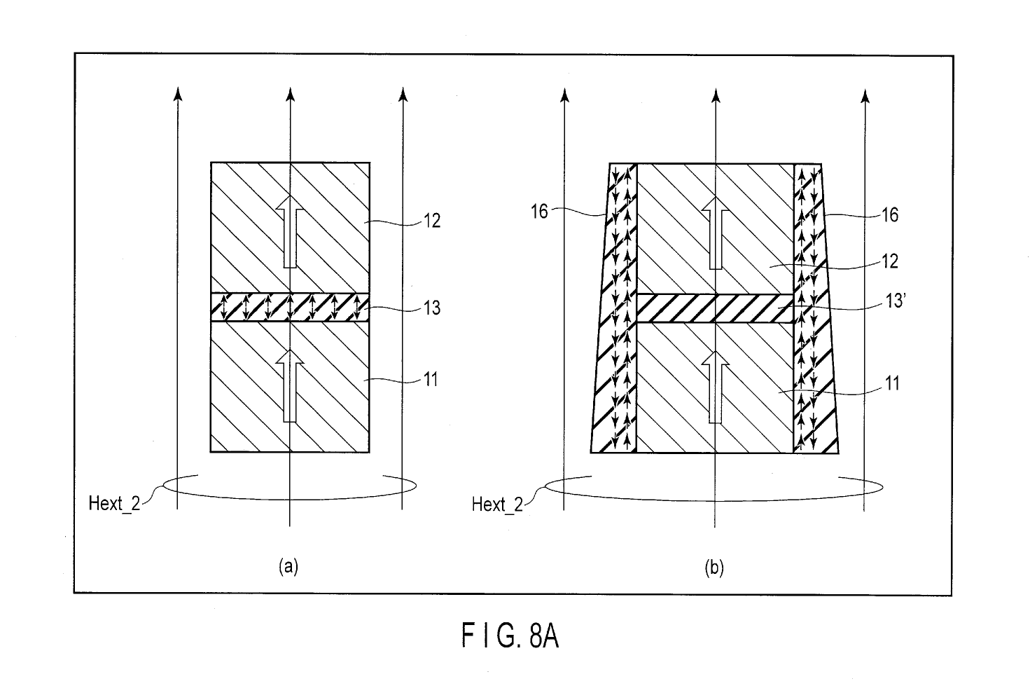

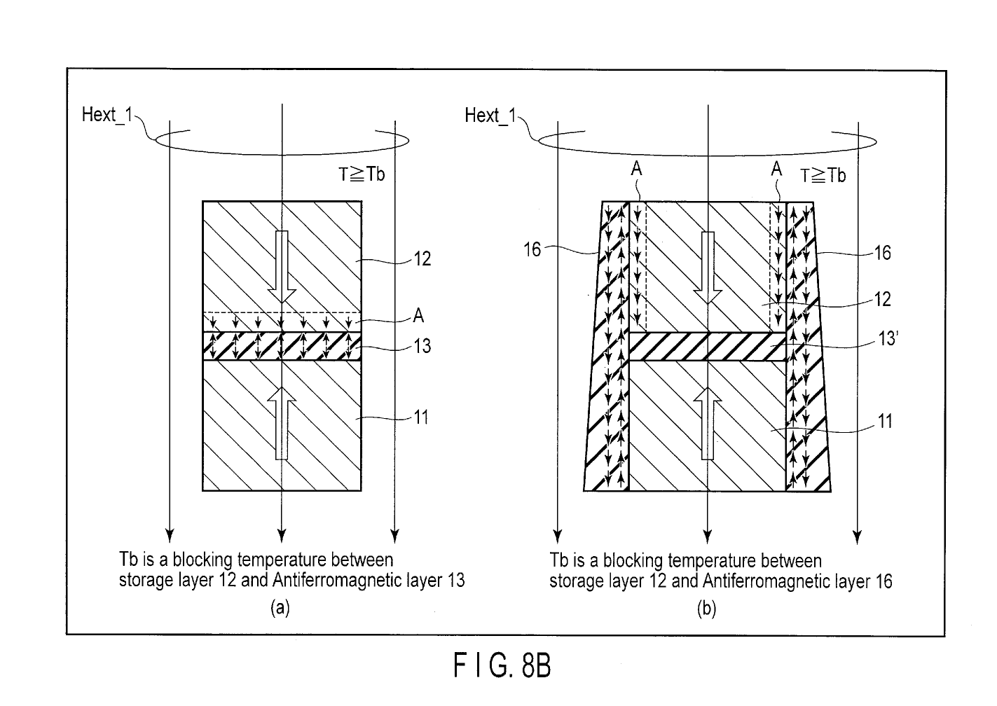

FIG. 8A and FIG. 8B show a second example of the manufacturing method. FIG. 8A(a) and FIG. 8B(a) correspond to FIG. 1A, and FIG. 8A(b) and FIG. 8(b) correspond to FIG. 2A.

First, as shown in FIG. 8A, the magnetoresistive element comprising the first magnetic layer 11, the second magnetic layer 12 and the antiferromagnetic insulating layer 13, or the magnetoresistive element comprising the first magnetic layer 11, the second magnetic layer 12, the nonmagnetic insulating layer 13′ and the antiferromagnetic insulating layer 16 is formed.

Subsequently, external magnetic field Hext_2 having the first direction (upward) is applied to shift the magnetization direction of the second magnetic layer 12 to the second direction.

Next, as shown in FIG. 8B, after the magnetization direction of the second magnetic layer 12 is shifted to the second direction, in a state where external magnetic field Hext_1 having the second direction (downward) opposite to the first direction (upward) is applied, the temperature of the magnetoresistive element, or specifically, the temperature of the wafer in which the magnetoresistive element is formed is increased to a temperature higher than the blocking temperature Tb between the second magnetic layer 12 and the antiferromagnetic insulating layers 13 and 16. After the increase, by changing the temperature to a temperature lower than the blocking temperature Tb, the second magnetic layer 12 is magnetically coupled with the antiferromagnetic insulating layers 13 and 16 by an exchange coupling, and area A whose magnetization direction is the second direction is formed in the second magnetic layer 12.

### (Blocking Temperature)

The blocking temperature Tb for the exchange coupling between the second ferromagnetic layer 12 and the antiferromagnetic insulating layers 13 and 16 differs depending on the materials constituting the layers.

For example, when the second magnetic layer 12 is CoFeB, the blocking temperature Tb changes depending on the materials of the antiferromagnetic insulating layers 13 and 16 as follows.

For example, the Tb of NiO comprising an NaCl structure is substantially 200° C. The Tb of α-Fe₂O₃ comprising a corundum structure is substantially 200° C. The Tb of each of MnO, FeO and Coo comprising an NaCl structure is room temperature. Each of the Tb of LaMnO₃ comprising a perovskite structure and the Tb of ZnFe₂O₄ comprising a spinel structure is room temperature.

### (5) Material Examples

In FIG. 1A, FIG. 1B, FIG. 1C, FIG. 2A, FIG. 2B, FIG. 3A and FIG. 3B, the first and second magnetic layers 11 and 12 contain a magnetic material of Co, Fe, Ni or Mn. The first and second magnetic layers 11 and 12 may contain oxygen (O). In this case, the amount of oxygen may change in the first and second magnetic layers 11 and 12.

The first and second magnetic layers 11 and 12 may comprise, for example, CoFeB, MgFeO or a lamination of CoFeB and MgFeO.

In case of the magnetoresistive element having a perpendicular magnetization, the first and second magnetic layers 11 and 12 preferably comprise TbCoFe having a perpendicular magnetic anisotropy, an artificial lattice in which Co and Pt are stacked, L1o-ordered FePt, and the like.

The third magnetic layer 14 comprises, for example, CoPt, CoRh or CoPd.

### 2. Application Example

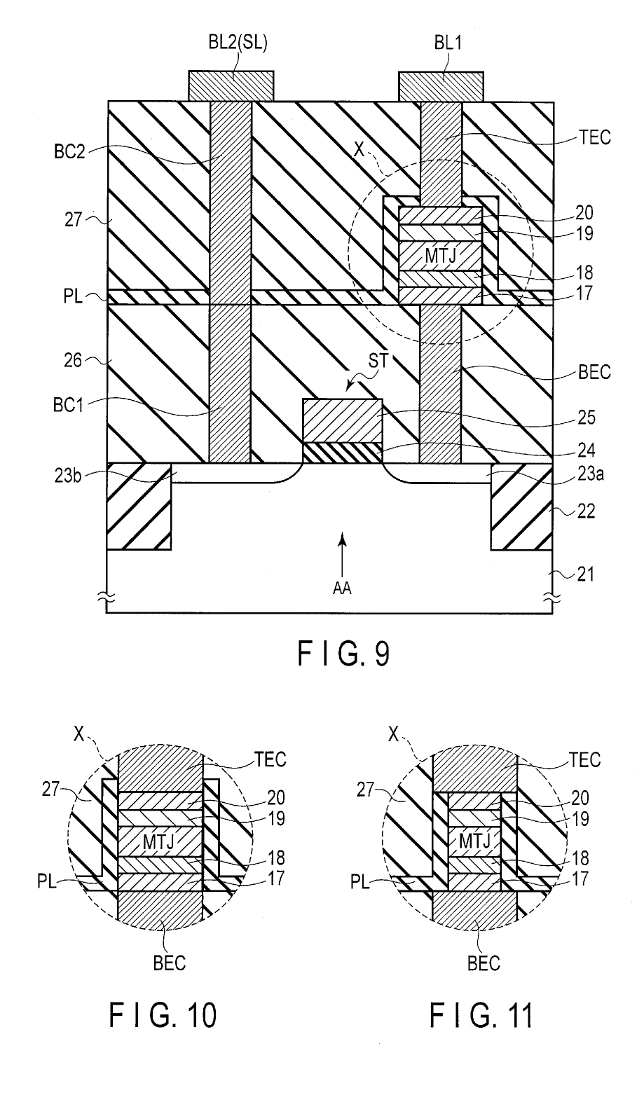

FIG. 9 shows an example of a memory cell of a magnetic memory.

In this example, the memory cell of the magnetic memory comprises a select transistor (for example, an FET) ST and a magnetoresistive element MTJ. The magnetoresistive element MTJ is the magnetoresistive element of each of the first to third embodiments.

The select transistor ST is provided in an active area AA in a semiconductor substrate 21. The active area AA is surrounded by an element separation insulating layer 22 in the semiconductor substrate 21. In this example, the element separation insulating layer 22 comprises a shallow-trench-isolation (STI) structure.

The select transistor ST comprises source/drain diffusion layers 23a and 23b in the semiconductor substrate 21, a gate insulating layer 24 on a channel between source/drain diffusion layers 23a and 23b, and a gate electrode 25 on the gate insulating layer 24. The gate electrode 25 functions as a word line.

An interlayer insulating layer (for example, a silicon oxide layer) 26 covers the select transistor ST. Contact plugs BEC and BC1 are provided in the interlayer insulating layer 26. The upper surface of the interlayer insulating layer 26 is flat. A lower electrode (first electrode) 17 is provided on the interlayer insulating layer 26.

The lower electrode 17 comprises, for example, one of Al, Be, Mg, Ca, Sr, Ba, Sc, Y, La, Zr and Hf, an alloy containing one of Al, Be, Mg, Ca, Sr, Ba, Sc, Y, La, Zr and Hf, or a chemical compound of B and one of Al, Be, Mg, Ca, Sr, Ba, Sc, Y, La, Zr and Hf (for example, HfB, MgAlB, HfAlB, ScAlB, ScHfB or HfMgB).

The lower electrode 17 is connected to source/drain diffusion layer 23a of the select transistor ST via contact plug (bottom electrode contact) BEC. Contact plug BC1 is connected to source/drain diffusion layer 23b of the select transistor ST.

A foundation layer 18 is provided on the lower electrode 17. The foundation layer 18 is provided for crystallizing the magnetoresistive element MTJ. The foundation layer 18 preferably contains MgO or a nitrogen compound such as AlN, MgN, ZrN, NbN, SiN and AlTiN.

The magnetoresistive element MTJ is provided on the foundation layer 18. A cap layer 19 is provided on the magnetoresistive element MTJ. The cap layer 19 functions as a buffer layer which prevents the reaction between the magnetoresistive element MTJ and an upper electrode 20. The cap layer 19 comprises, for example, Pt, W, Ta or Ru.

The upper electrode 20 is provided on the cap layer 19. The upper electrode 20 comprises, for example, W, Ta, Ru, Ti, TaN or TiN.

In addition to the function as an electrode, the upper electrode 20 has a function as a mask used for patterning the magnetoresistive element MTJ. The upper electrode 20 preferably has a material which is low in the electrical resistance and is excellent in diffusion resistance, etching resistance, milling resistance and the like, such as a lamination of Ta/Ru.

The protective insulating layer (for example, a silicon nitride layer) PL covers a sidewall of the magnetoresistive element MTJ. An interlayer insulating layer (for example, a silicon oxide layer) 27 is provided on the protective insulating layer PL, and covers the magnetoresistive element MTJ. The upper surface of the interlayer insulating layer 27 is flat. Bit lines BL1 and BL2 are provided on the interlayer insulating layer 27.

Bit line BL1 is connected to the upper electrode 20 via contact plug (top electrode contact) TEC. Bit line BL2 is connected to contact plug BC1 via contact plug BC2.

In this example, the magnetoresistive element MTJ is larger than contact plug BEC in a direction (in-plane direction) parallel to the top surface of the semiconductor substrate 21.

However, the size of the magnetoresistive element MTJ is not limited to this structure. For example, as shown in FIG. 10, in the direction parallel to the top surface of the semiconductor substrate 21, the magnetoresistive element MTJ may be the same as contact plug BEC in size. As shown in FIG. 11, in the direction parallel to the top surface of the semiconductor substrate 21, the magnetoresistive element MTJ may be smaller than contact plug BEC.

Area X of FIG. 10 and FIG. 11 corresponds to area X of FIG. 9.

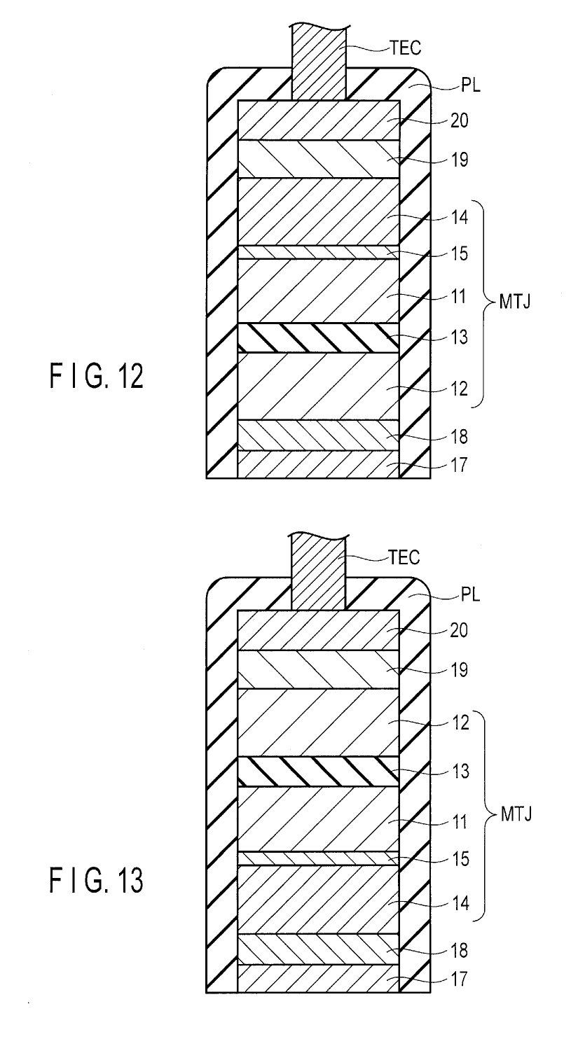

FIG. 12 and FIG. 13 show examples of the magnetoresistive element MTJ of each of FIG. 9 to FIG. 11.

The magnetoresistive element MTJ of FIG. 12 is an example in which the magnetoresistive element of FIG. 10 is applied to the memory cell of the magnetic memory of each of FIG. 9 to FIG. 11 as a top-pin type.

In this example, the second magnetic layer (storage layer) 12 is provided on the foundation layer 18. The antiferromagnetic insulating layer 13 is provided on the second magnetic layer 12. The first magnetic layer (reference layer) 11 is provided on the antiferromagnetic insulating layer 13. The third magnetic layer (shift cancelling layer) 14 is provided above the first magnetic layer 11 via the nonmagnetic-and-conductive layer 15.

The cap layer 19 is provided on the third magnetic layer 14.

The other structures are the same as the structures of the memory cell of the magnetic memory of each of FIG. 9 to FIG. 11. The elements identical to those of FIG. 9 to FIG. 11 are denoted by the same reference numbers. Thus, explanations of such elements are omitted.

The magnetoresistive element MTJ of FIG. 13 is an example in which the magnetoresistive element of FIG. 10 is applied to the memory cell of the magnetic memory of each of FIG. 9 to FIG. 11 as a bottom-pin type.

In this example, the third magnetic layer (shift cancelling layer) 14 is provided on the foundation layer 18. The first magnetic layer (reference layer) 11 is provided above the third magnetic layer 14 via the nonmagnetic-and-conductive layer 15. The antiferromagnetic insulating layer 13 is provided on the first magnetic layer 11. The second magnetic layer (storage layer) 12 is provided on the antiferromagnetic insulating layer 13.

The cap layer 19 is provided on the second magnetic layer 12.

The other structures are the same as the structures of the memory cell of the magnetic memory of each of FIG. 9 to FIG. 11. The elements identical to those of FIG. 9 to FIG. 11 are denoted by the same reference numbers. Thus, explanations of such elements are omitted.

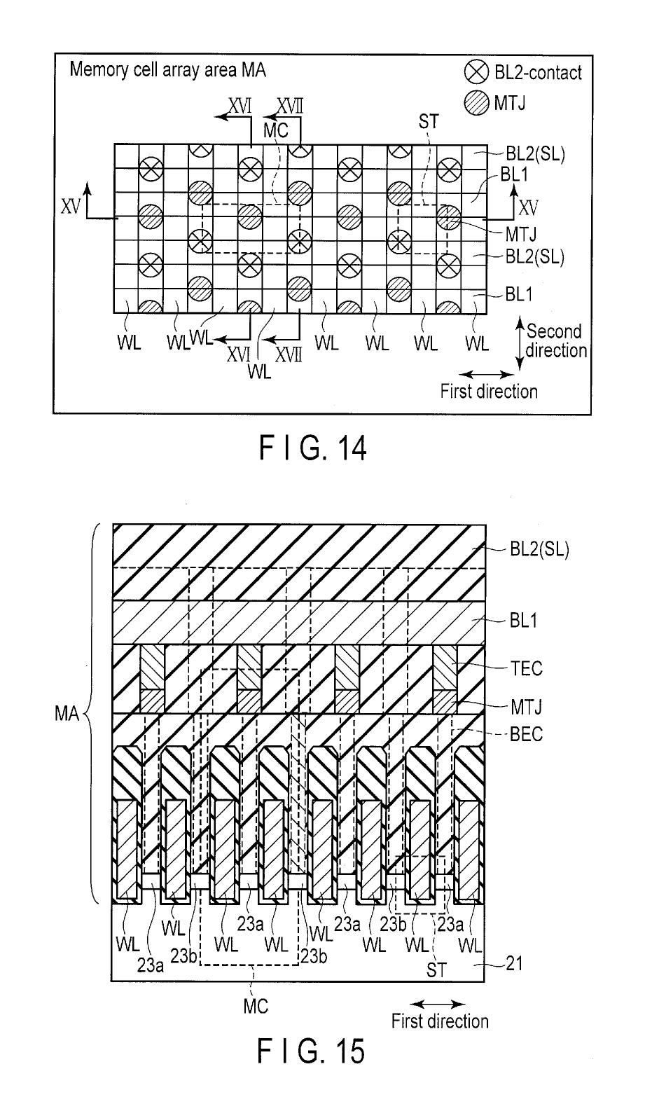

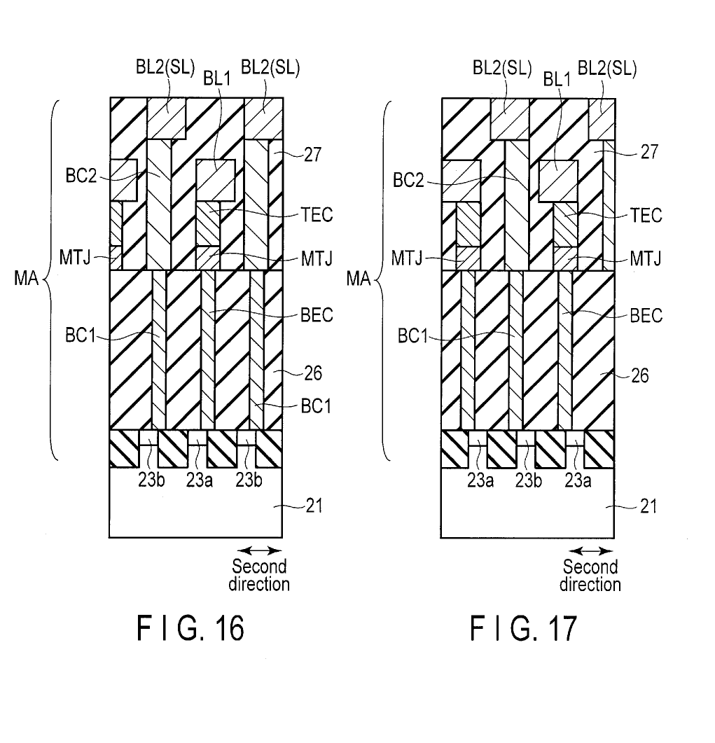

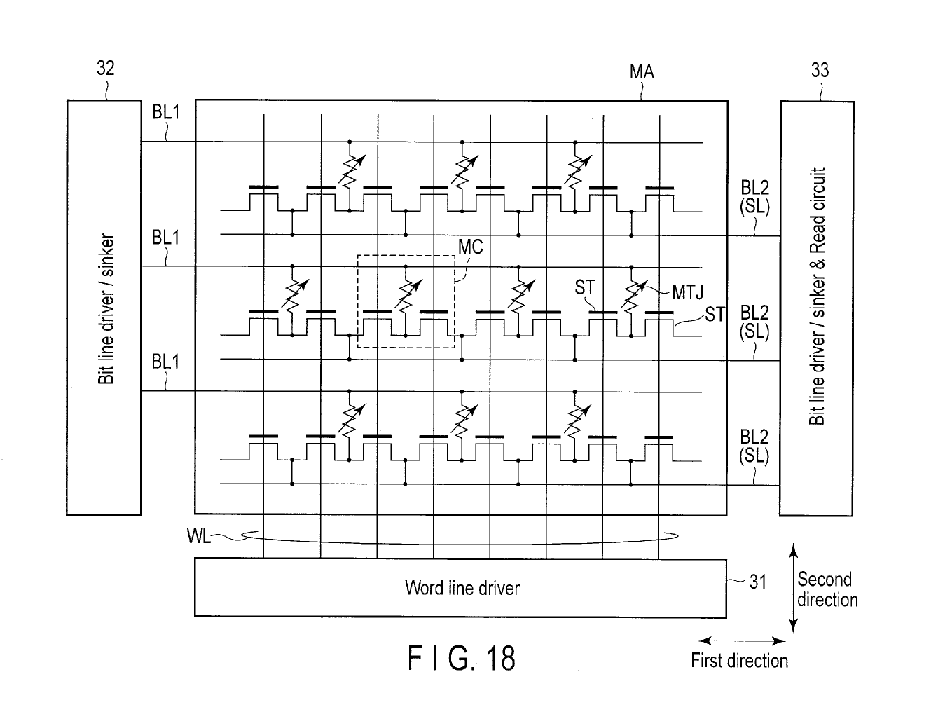

FIG. 14 to FIG. 18 show an example of a memory cell array area of a magnetic random access memory. FIG. 14 is a plane view of the memory cell array area. FIG. 15 is a cross-sectional view taken along line XV-XV of FIG. 14. FIG. 16 is a cross-sectional view taken along line XVI-XVI of FIG. 14. FIG. 17 is a cross-sectional view taken along line XVII-XVII of FIG. 14. FIG. 18 shows an equivalent circuit of the memory cell array area of FIG. 14 to FIG. 17.

In FIG. 14 to FIG. 17, the elements identical to those of FIG. 9 to FIG. 13 are denoted by the same reference numbers.

In this example, a two-transistor, one-element type is explained. In this type, one memory cell MC in a memory cell array area MA comprises two select transistors ST and one magnetoresistive element MTJ. However, the above first to third embodiments are not limited to this type. The first to third embodiments can be applied to other types of memory cell array area MA such as a one-transistor, one-element type and a cross-point type.

A plurality of memory cells MC are arranged in an array state on the semiconductor substrate 21. Each memory cell MC comprises two select transistors ST on the semiconductor substrate 21, and one magnetoresistive element MTJ connected to the two select transistors ST in common.

Each select transistor ST comprises source/drain diffusion layers 23a and 23b in the semiconductor substrate 21, a word line WL as a gate electrode on the channel between source/drain diffusion layers 23a and 23b. The word line WL extends in the second direction and is connected to a word line driver 31.

The magnetoresistive element MTJ is provided above source/drain diffusion layer 23a, and is connected to source/drain diffusion layer 23a. Bit line BL1 is provided above the magnetoresistive element MTJ, and is connected to the magnetoresistive element MTJ. Bit line BL1 extends in the first direction, and is connected to a bit line driver/sinker 32.

Bit line BL2 is provided above source/drain diffusion layer 23b, and is connected to source/drain diffusion layer 23b. For example, bit line BL2 also functions as a source line SL connected to a sense amplifier at the time of a reading operation. Bit line BL2 extends in the first direction, and is connected to a bit line driver/sinker and read circuit 33.

This layout of the memory cell array area is merely an example, and may be arbitrarily modified. In this example, when the memory cell array area MA is viewed from above the semiconductor substrate 21, the positional relationships among source/drain diffusion layers 23a and 23b, the magnetoresistive element MTJ and bit line BL1 are shifted in the second direction. However, for example, the presence or absence of the shift, or the shift amount may be arbitrarily changed.

In this example, bit lines BL1 and BL2 are formed in line layers different from each other. However, bit lines BL1 and BL2 may be formed in the same line layer.

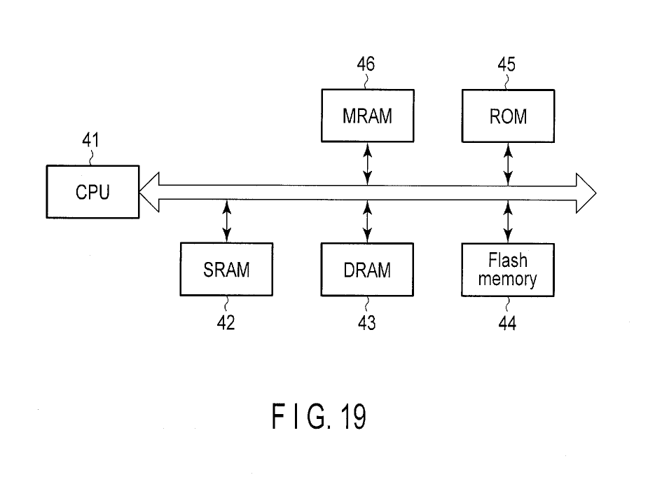

FIG. 19 shows an example of a memory system in a processor.

A CPU 41 controls an SRAM 42, a DRAM 43, a flash memory 44, a ROM 45 and an MRAM (magnetic random access memory) 46.

The above first to third embodiments are applied to the memory cell (magnetoresistive element) in the MRAM 46.

The MRAM 46 can be used as a substitute for each of the SRAM 42, the DRAM 43, the flash memory 44 and the ROM 45. Accordingly, at least one of the SRAM 42, the DRAM 43, the flash memory 44 and the ROM 45 may be omitted.

The MRAM 46 can be used as a nonvolatile cache (for example, an L2 cache).

### 3. Conclusion

According to the above embodiments, it is possible to cancel the shift of magnetization inversion property of the storage layer due to the stray magnetic field from the reference layer, without using a shift cancelling layer or without enlarging the thickness of the shift cancelling layer in the perpendicular direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive element comprising:
a first magnetic layer having an invariable magnetization;
a second magnetic layer having a variable magnetization; and
a first insulating layer between the first and second magnetic layer, the first insulating layer including at least one of a nickel oxide, an iron oxide, a cobalt oxide, a manganese oxide, LaMnO₃ and ZnFe₂O₄.

2. The element of claim 1, wherein
the first insulating layer comprises an antiferromagnetic insulating layer.

3. The element of claim 1, wherein
the second magnetic layer includes an area which is magnetic coupled with the first insulating layer by an exchange coupling and which has a magnetization direction opposite to a magnetization direction of the first magnetic layer.

4. The element of claim 1, further comprising:
a second insulating layer between the first magnetic layer and the first insulating layer.

5. The element of claim 1, further comprising:
a third magnetic layer having an invariable magnetization and having a magnetization direction opposite to the magnetization direction of the first magnetic layer.

6. The element of claim 1, wherein
the first insulating layer comprises NaCl-structure which is (001)-oriented in a direction in which the first and second magnetic layers are stacked.

7. The element of claim 1, wherein
each of the first and second magnetic layers has a remanent magnetization in a direction in which the first and second magnetic layers are stacked.

8. The element of claim 1, wherein
the magnetization direction of the second magnetic layer is changed by a write current which flows between the first and second magnetic layers.

9. A magnetoresistive element comprising:
a first magnetic layer having an invariable magnetization;
a second magnetic layer having a variable magnetization;
a first insulating layer which is adjacent to a sidewall of the second magnetic layer in a direction perpendicular to a direction in which the first and second magnetic layer are stacked, the first insulating layer including at least one of a nickel oxide, an iron oxide, a cobalt oxide, a manganese oxide, LaMnO₃ and ZnFe₂O₄; and
a second insulating layer between the first and second magnetic layers.

10. The element of claim 9, wherein
the first insulating layer comprises an antiferromagnetic insulating layer.

11. The element of claim 9, wherein
the second magnetic layer includes an area which is magnetic coupled with the first insulating layer by an exchange coupling and which has a magnetization direction opposite to a magnetization direction of the first magnetic layer.

12. The element of claim 9, wherein
the first insulating layer is adjacent to a sidewall of the first magnetic layer in the direction perpendicular to the direction in which the first and second magnetic layer are stacked, and
the first magnetic layer includes an area which is magnetic coupled with the first insulating layer by the exchange coupling and which has a magnetization direction opposite to the magnetization direction of the first magnetic layer.

13. The element of claim 9, further comprising:
a third magnetic layer having an invariable magnetization and having a magnetization direction opposite to the magnetization direction of the first magnetic layer.

14. The element of claim 9, wherein
the first insulating layer comprises NaCl-structure which is (001)-oriented in a direction in which the first and second magnetic layers are stacked.

15. The element of claim 9, wherein
each of the first and second magnetic layers has a remanent magnetization in a direction in which the first and second magnetic layers are stacked.

16. The element of claim 9, wherein
the magnetization direction of the second magnetic layer is changed by a write current which flows between the first and second magnetic layers.

17. A method of manufacturing the element of claim 1, the method comprising:
forming the first magnetic layer, the second magnetic layer, and the first insulating layer;
directing the magnetization direction in the area to a first direction, by changing a temperature of the element to a first value larger than a blocking temperature between the second magnetic layer and the first insulating layer and changing the temperature of the element from the first value to a second value smaller than the blocking temperature in a state which is applied an external magnetic field in the first direction; and
applying an external magnetic field in a second direction opposite to the first direction, after directing the magnetization direction in the area to the first direction.

18. A method of manufacturing the element of claim 9, the method comprising:
forming the first magnetic layer, the second magnetic layer, and the first insulating layer;
directing the magnetization direction in the area to a first direction, by changing a temperature of the element to a first value larger than a blocking temperature between the second magnetic layer and the first insulating layer and changing the temperature of the element from the first value to a second value smaller than the blocking temperature in a state which is applied an external magnetic field in the first direction; and
applying an external magnetic field in a second direction opposite to the first direction, after directing the magnetization direction in the area to the first direction.

19. A method of manufacturing the element of claim 1, the method comprising:
forming the first magnetic layer, the second magnetic layer, and the first insulating layer;
applying an external magnetic field in a first direction;
directing the magnetization direction in the area to a second direction opposite to the first direction, by changing a temperature of the element to a first value larger than a blocking temperature between the second magnetic layer and the first insulating layer and changing the temperature of the element from the first value to a second value smaller than the blocking temperature in a state which is applied an external magnetic field in the second direction, after applying the external magnetic field in the first direction.

20. A method of manufacturing the element of claim 9, the method comprising:
forming the first magnetic layer, the second magnetic layer, and the first insulating layer;
applying an external magnetic field in a first direction;
directing the magnetization direction in the area to a second direction opposite to the first direction, by changing a temperature of the element to a first value larger than a blocking temperature between the second magnetic layer and the first insulating layer and changing the temperature of the element from the first value to a second value smaller than the blocking temperature in a state which is applied an external magnetic field in the second direction, after applying the external magnetic field in the first direction.
